(19) United States
(12) Patent Application Publication
(10) Pub. No.: US 2007/0145445 A1
(43) Pub. Date: Jun. 28, 2007

(54) CMOS Image Sensor and Method for Manufacturing the Same

(76) Inventor: Seong Hee Jeong, Namdong-gu (KR)

Correspondence Address: SALIWANCHIK LLOYD & SALIWANCHIK;A PROFESSIONAL ASSOCIATION, PO BOX 142950, GAINESVILLE, FL, 32614-2950, US

(21) Appl. No.: 11/614,096

(22) Filed: Dec. 21, 2006

(30) Foreign Application Priority Data
Dec. 28, 2005 (KR) 10-2005-0131291

(51) Int. Cl. H01L 31/113; H01L 21/00

(52) U.S. Cl. 257/292; 257/294; 438/70; 438/69

(57) ABSTRACT

A method for manufacturing a CMOS image sensor is provided. The method includes: forming a photodiode on a semiconductor sustrate; forming a color filter layer on the photodiode; forming a planar layer on the color filter layer; forming a first microlens on the planar layer; and forming a second microlens on the first microlens. According to the preferred embodiment, a reflow process can be avoided in the forming of the microlenses.

### RELATED APPLICATION(S)

This application claims priority under 35 U.S.C. §119(e) of Korean Patent Application No. 10-2005-0131291 filed Dec. 28, 2005, which is incorporated herein by reference in its entirety.

### FIELD OF THE INVENTION

The present invention relates to a CMOS image sensor and a method for manufacturing the same.

### BACKGROUND OF THE INVENTION

An image sensor is a semiconductor device for converting optical images into electric signals, and is mainly classified as a charge coupled device (CCD) image sensor or a complementary metal oxide semiconductor (CMOS) image sensor.

The CMOS image sensor includes a photodiode for detecting light and a logic circuit for converting detected light into electric signals for image data. As the quantity of light capable of being received in the photodiode increases, the photosensitivity of the image sensor improves.

To improve the photosensitivity of an image sensor, either a fill factor, which is the ratio of a photodiode area to the whole area of the image sensor, must be increased, or a photo-gathering technology is used to change the path of light incident onto an area other than the photodiode area towards the photodiode.

A representative example of the photo-gathering technology is a microlens. That is, a convex microlens is formed on a top surface of the photodiode using a material having superior light transmittance, thereby refracting the path of incident light in such a manner that a greater amount of light can be transmitted into the photodiode area.

In this case, light parallel to an optical axis of the microlens is refracted by the microlens, so that the light is focused at a predetermined position on the optical axis.

Hereinafter, the CMOS image sensor according to the related art will be described with reference to accompanying drawings.

FIG. 1 is a sectional view illustrating a structure of a conventional CMOS image sensor.

Referring to FIG. 1, the CMOS image sensor includes at least one photodiode 12 formed on a semiconductor substrate 11 to generate charges corresponding to the quantity of incident light; an interlayer dielectric layer (not shown) formed on the entire surface of the semiconductor substrate 11 including photodiodes 12; a protective layer 13 formed on the interlayer dielectric layer; red (R), green (G) and blue (B) color filter layers 14 formed on the protective layer 13 to allow light having a specific wavelength band to pass therethrough; a planarization layer 15 formed on the color filter layer 14; and a microlens 16 having a convex shape with predetermined curvature formed on the planarization layer 15 to allow light to pass through the corresponding color filter layer 14 and to guide light into the photodiodes 12.

In addition, although not shown in the figure, the CMOS image sensor can further include an optical shielding layer formed in the interlayer dielectric layer so as to prevent light from being incident onto an area other than the photodiode 12.

In the CMOS image sensor described above, one of the most important processes exerting influence upon the performance of the image sensor is the process of forming the microlens 16.

Because the microlens 16 is formed through reflowing resist, adjacent resists may become bonded with each other in the process of manufacturing the microlens 16, thereby causing problems such as deformation of the microlens or a bridge between the microlenses.

In addition, it is difficult to mass-reproduce the microlens having a predetermined shape.

Thus, various processing technologies regarding the microlens are currently being studied.

### BRIEF SUMMARY

An object of embodiments of the present invention is to provide a method for manufacturing a CMOS image sensor, capable of forming a microlens without using a reflow process.

Another object of embodiments of the present invention is to provide a method for manufacturing a CMOS image sensor, capable of improving the characteristics of the image sensor by improving a curvature of the microlens.

An embodiment of the present invention provides a method for manufacturing a CMOS image sensor, the method comprising the steps of: forming a photodiode on a semiconductor substrate; forming a color filter layer on the photodiode; forming a planarization layer on the color filter layer; forming a first microlens on the planarization layer; and forming a second microlens on the first microlens.

An embodiment of the present invention also provides a CMOS image sensor comprising: a photodiode formed on a semiconductor substrate; a color filter layer formed on the photodiode; a planarization layer formed on the color filter layer; a first microlens formed on the planarization layer; and a second microlens formed on the first microlens.

### BRIEF DESCRIPTION OF THE DRAWINGS

FIG. 1 is a sectional view illustrating a structure of a conventional CMOS image sensor.

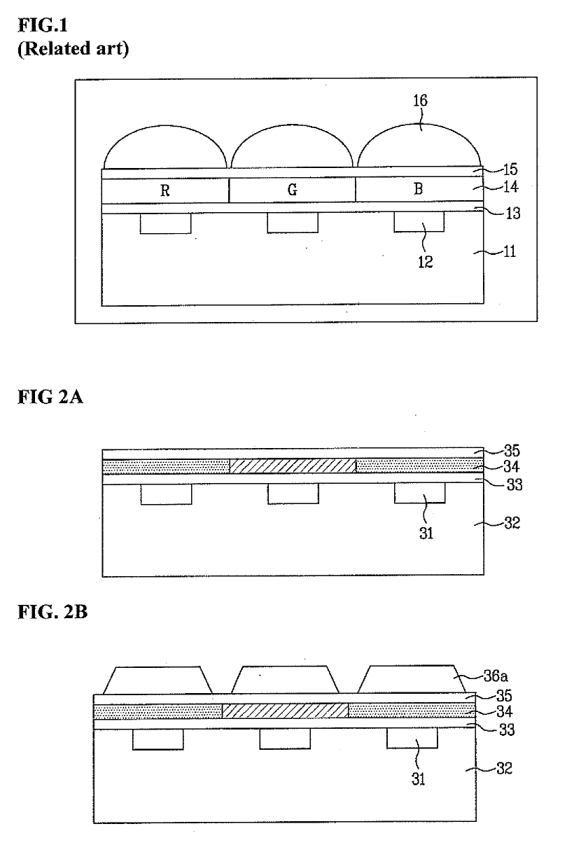

FIG. 2A through 2D are sectional views illustrating a procedure for manufacturing an image sensor according to an embodiment of the present invention.

### DETAILED DESCRIPTION OF THE INVENTION

Hereinafter, a method for manufacturing a CMOS image sensor according to preferred embodiments of the present invention will be described in detail with reference to the accompanying drawings.

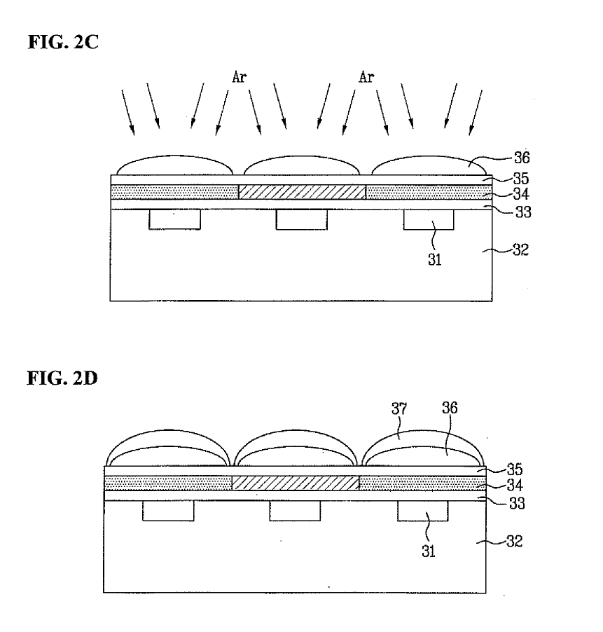

FIG. 2A through 2D are sectional views illustrating the procedure for manufacturing an image sensor according to an embodiment of the present invention.

Referring to FIG. 2A, an interlayer dielectric layer(not shown) can be formed on the entire surface of a semiconductor substrate to generate charges corresponding to quantity of incident light.

In an embodiment the interlayer dielectric layer can be prepared in the form of a multi-layer, and although not shown, after forming one interlayer dielectric layer, an optical shielding layer can be formed to prevent light from being incident onto an area other than the photodiode 31, and then another interlayer dielectric layer can be formed thereupon.

After that, a planarized protective layer 33 can be formed on the interlayer dielectric layer to protect devices from moisture and scratch.

Then, red (R), green (G) and blue (B) color filter layers 34 can be formed on the protective layer 33 to filter light of specific wavelength bands. The color filter layers can be formed using dyable resist by coating and patterning processes.

After that, a planarized planar layer 35 can be formed on the color filter layer 34 in order to adjust the focal length and to ensure planarization degree for forming the lens layer.

Referring to FIG. 2B, a material layer for the microlens such as resist or SiON can be deposited on the planar layer 35.

Then, the material layer for the microlens can be selectively patterned by an exposure and development process to form a microlens pattern 36a on the planar layer 35 corresponding to each photodiode 31.

As shown in FIG. 2C, an Ar sputtering process can be performed on the entire surface of the microlens pattern 36a to form a first microlens 36 having a convex shape.

When the Ar sputtering process is performed on the microlens pattern 36a, 45° etching is performed due to the characteristic of the Ar sputtering, so that the trapezoidal shape of the microlens pattern is gradually changed into the convex shape.

For example, the Ar sputtering can be performed under the condition of a source power 1000 w, a bias power 300 w, a pressure of 20 mT or less, and 300 sccm of Ar. The curvature of the microlens can be improved by the Ar sputtering.

Referring to FIG. 2D, a second microlens 37 can be coated on the first microlens 36 having the convex shape. Then, ultraviolet rays can be illuminated onto the entire surface of the second microlens 37, thereby hardening the second microlens. Thus, an optimum radius of curvature can be maintained. In one embodiment, a spin coating process can be used to coat resist for the second microlens 37. The second microlens 37 can include resist or SiON.

Thus, when manufacturing the CMOS image sensor according to embodiments of the present invention, the microlens pattern having a trapezoidal shape can be formed using a defocus in order to form the first microlens pattern. Then the first microlens having the convex shape can be formed by performing the Ar sputtering process on the entire surface of the first microlens pattern. Next, the second microlens can be formed on the first microlens having the convex shape, thereby further improving the curvature of the microlens.

As described above, the method for manufacturing the CMOS image sensor according to embodiments of the present invention has the following advantages.

The Ar sputtering process can be performed on the entire surface of the microlens pattern having a trapezoidal shape such that the microlens pattern is gradually changed into a convex shape and then the second microlens is simply coated thereon without performing a reflow process. Thus, the coating process for the second microlens can be controlled by adjusting only the thickness of The microlens material and the size of the microlens pattern, thereby preventing a bridge between the microlenses caused by a conventional heat treatment.

It should be understood that the examples and embodiments described herein are for illustrative purposes only and that various modifications or changes in light thereof will be suggested to persons skilled in the art and are to be included within the spirit and purview of this application.

I claim:

1. A method for manufacturing a CMOS image sensor, comprising:
forming a photodiode on a semiconductor substrate;
forming a color filter layer on the photodiode;
forming a planar layer on the color filter layer;
forming a first microlens on the planar layer; and
forming a second microlens on the first microlens.

2. The method according to claim 1, wherein forming the first microlens comprises forming a microlens pattern and performing an Ar sputtering process to the microlens pattern.

3. The method according to claim 2, wherein the microlens pattern has a trapezoidal sectional shape.

4. The method according to claim 2, wherein the Ar sputtering process is performed at a pressure of 20 mT or less.

5. The method according to claim 1, wherein forming the second microlens on the first microlens comprises coating a microlens material on the first microlens.

6. The method according to claim 5, wherein the second microlens is formed on the first microlens by a spin coating process.

7. The method according to claim 1, wherein the first microlens comprises resist or SiON.

8. The method according to claim 1, wherein the second microlens comprises resist or SiON.

9. The method according to claim 1, further comprising radiating ultraviolet rays after forming the second microlens.

10. A CMOS image sensor, comprising:
a photodiode formed on a semiconductor substrate;
a color filter layer formed on the photodiode;
a planar layer formed on the color filter layer;
a first microlens formed on the planar layer; and
a second microlens formed on the first microlens.

11. The CMOS image sensor according to claim 10, wherein the first microlens comprises resist or SiON.

12. The CMOS image sensor according to claim 10, wherein the second microlens comprises resist or SiON.
